(19) United States
(12) Patent Application Publication
(10) Pub. No.: US 2005/0243585 A1
(43) Pub. Date: Nov. 3, 2005

(54) Human-readable indicia for archival digital data storage

(75) Inventors: Alan B. Marchant, Fairport, NY (US); Daniel E. Matukewicz, Rochester, NY (US); James J. Minno, Webster, NY (US)

Correspondence Address: Thomas H. Close;Patent Legal Staff, Eastman Kodak Company, 343 State Street, Rochester, NY, 14650-2201, US

(73) Assignee: Eastman Kodak Company

(21) Appl. No.: 09/978,955

(22) Filed: Oct. 16, 2001

(51) Int. Cl. G11C 27/00

(52) U.S. Cl. 365/45

(57) ABSTRACT

A method for archival digital data storage includes processing a digital data file to generate one or more images that summarize the information content of the data file, recording the data file in a digital format on a data band of a digital recording medium, and recording the summary image(s) as human-readable indicia on a data band, such human-readable indicia being adjacent to or embedded within the digitally formatted data file.

### FIELD OF THE INVENTION

The present invention relates to human-readable indicia for archival digital data storage.

### BACKGROUND OF THE INVENTION

For archival data storage, information is recorded on removable media and stored off-line, e.g. in a vault, a jukebox, or other repository. Often, many files of information are recorded and stored on a single media unit. To recover information from an archive, the media unit is retrieved from storage and then examined to verify that it contains the desired information.

In many cases, a clear directory link to the desired information may not exist. For example, a future user may need to mine a data archive based on information content that was not originally appreciated or indexed. It is also possible that a compatible digital readout device will not be available to reconstruct digitally archived data when it is needed. This can occur because of product obsolescence, changes in digital protocols and file formats, or technology migration.

The future archivist may have access to advanced technology to scan and reconstruct digital data patterns from a wide variety of media types. Yet lack of information about data provenance, file contents, data formats, and the specific codes for modulation, error correction, data compression, etc. would still make access to digital archives impractically slow and costly.

One solution to the problem of obsolescence is to store information as images on an analog recording medium, such a photographic film, microfilm, or microfiche. Analog data storage is human-readable in that the data may be read or understood using only imaging means such as a microscope or other general purpose imaging system. A specialized digital channel is not required. The recorded image pattern need not be visible to the naked eye. The imaging system can magnify the image pattern and/or map it onto an image display device.

Analog data formats are incompatible with the critical needs for increased storage capacity, data rate, and data reliability. WO 00/28726 discloses an optical recording format that includes both human-readable and digital representations of the data. This addresses the concern of data reliability, but greatly reduces storage capacity and recording data rate.

### SUMMARY OF THE INVENTION

It is an object of this invention to record human-readable indicia on a digital recording medium together with corresponding digital data files.

It is a further object of this invention to record human-readable information on a data storage medium that may aid in future recovery of the information that is digitally recorded on the medium.

It is a further object of this invention to provide human-readable thumbnail images for identification of the content of archived digital image files without recourse to a digital readout device.

These objects are achieved by a method for archival digital data storage, comprising the steps of:
a) processing a digital data file to generate one or more images that summarize the information content of the data file;
b) recording the data file in a digital format on a data band of a digital recording medium; and
c) recording the summary image(s) as human-readable indicia on a data band, such human-readable indicia being adjacent to or embedded within the digitally formatted data file.

### Advantages

A feature of the present invention is that, during the recording process, it provides human-readable indicia with associated digital formatted data files, which can act as a directory for subsequent retrieval purposes.

The present invention has the advantage of enhancing the archival value of data stored on a digital recording medium by providing human-readable indicia. Human-readable indicia greatly increase the speed and reliability of access to archived digital information when the original digital readout means are no longer available. The human-readable indicia may include analog text patterns displaying directory information and metadata. They also may include diagrams illustrating the organization of files on the medium, data encoding formats, data readout methods, etc.

It is a further advantage of the present invention that it provides human-readable identification of the contents of individual data files on a digital storage medium. Alphanumeric images of the file name, content summary, file type, creator, etc. may be recorded adjacent to the digital data file. Viewable versions of representative tables, diagrams, drawings, or icons may be provided.

It is a further advantage of the present invention that it provides for archival indexing of dense image files, such as digitized motion pictures. A thumbnail image may be attached to any frame of such an image file, permitting future identification of desired images or clips without a prior availability of a matched digital readout system or indeed any external index to the file contents.

It is a further advantage of the present invention that the human-readable indicia may be combined with a digital data recording without substantially reducing the data rate or storage capacity.

### BRIEF DESCRIPTION OF THE DRAWINGS

FIG. 1 describes the process of digital data storage and retrieval according to the prior art;

FIG. 2 illustrates readout of information archived in an analog format according to the prior art;

FIG. 3 shows a system for recording data on an optical recording medium according to the prior art;

FIG. 4 illustrates a format for digital data recording with human-readable indicia according to the present invention;

FIG. 5 describes a process for recovering the contents of archived digital data files using human-readable indicia;

FIG. 6 shows an image file with embedded human-readable thumbnail images; and

FIG. 7 shows the operation of a multi-channel optical recording system suitable for recording human-readable indicia together with digital data files.

### DETAILED DESCRIPTION OF THE INVENTION

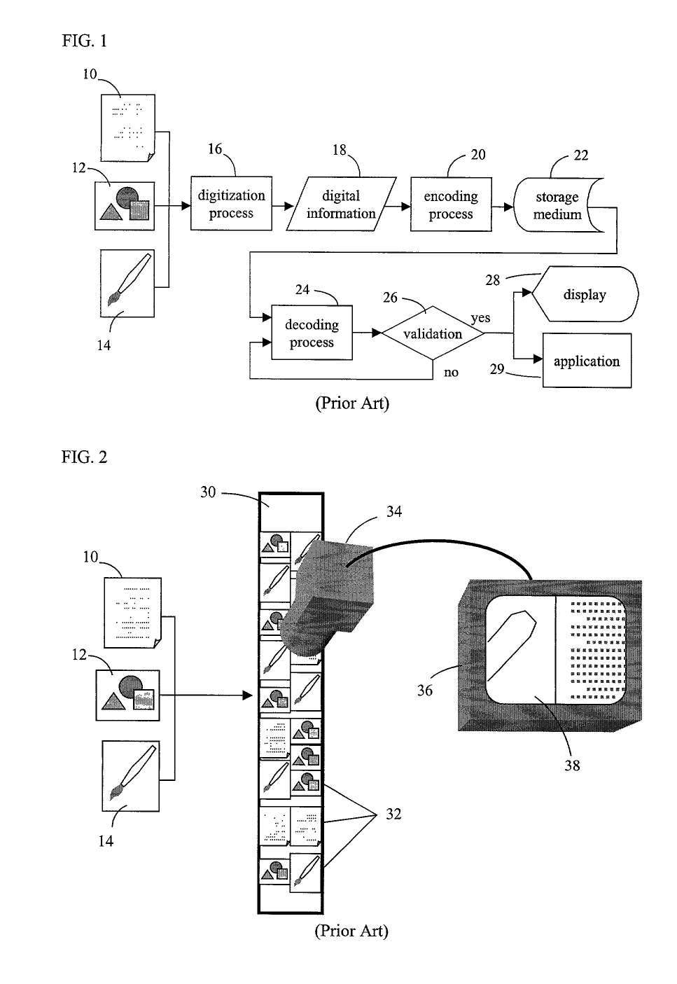

A typical prior art process for archival digital data storage and retrieval is illustrated in FIG. 1. Information elements such as documents, drawings, or pictures (10, 12, and 14, respectively) are processed by a digitizer 16 to create digital data files 18. The digital data files include all the useful information from the original information elements, represented by digital information units, such a bits or bytes. One or more digital encoding transformations are applied to the digital data file by an encoder 20. The code transformations may include, for example, data compression, error detection and correction coding, and channel modulation. The encoded digital data file is then recorded as a stable spatial pattern on the recording surface of a digital storage medium 22. For archival applications, the storage medium may be stored separately from the recording hardware but accessible for future data retrieval, which can extend for a number of years.

Digital data signals retrieved from the storage medium are processed by a decoder 24 to reproduce a digital data file. The retrieval process includes a data content validation check 26 to verify whether the reproduced digital information is the desired data file. Validation may include comparing incorporated file descriptors with independent directory information. Alternatively, the file contents may be searched for desired data. If the content validation check is negative, the data storage system may recover another data file from the digital storage medium. When the validation check indicates that the correct data file has been retrieved, it is delivered for use. For example, the information in the digital data file may be converted to a human-readable representation by a display unit 28 or utilized directly by a data application 29.

Archival access to information on a digital storage medium is subject to the risk of system obsolescence. In the absence of a functioning readout system, including decoder hardware and software, it is not possible to recover the digital data files, or even to verify whether the desired information is stored on a particular media unit. This archival limitation does not apply to the prior art method of analog data storage and readout illustrated in FIG. 2. Information elements such as documents, drawings, or pictures (10, 12, and 14) are recorded on an analog storage medium 30 as images 32. The images are stable spatial patterns with features that are continuously mapped from the corresponding information elements.

Information on the analog storage medium is recovered using an imaging system 34 coupled to an image display system 36 that displays an image 38 of the original information element. The imager and display systems may be separate systems, for example a camera coupled to a monitor, or they may be functions of the same system, such as a microscope. The imaging system need not be an optical sensor; it may be any type of sensor that reconstructs the spatial patterns of the recorded images.

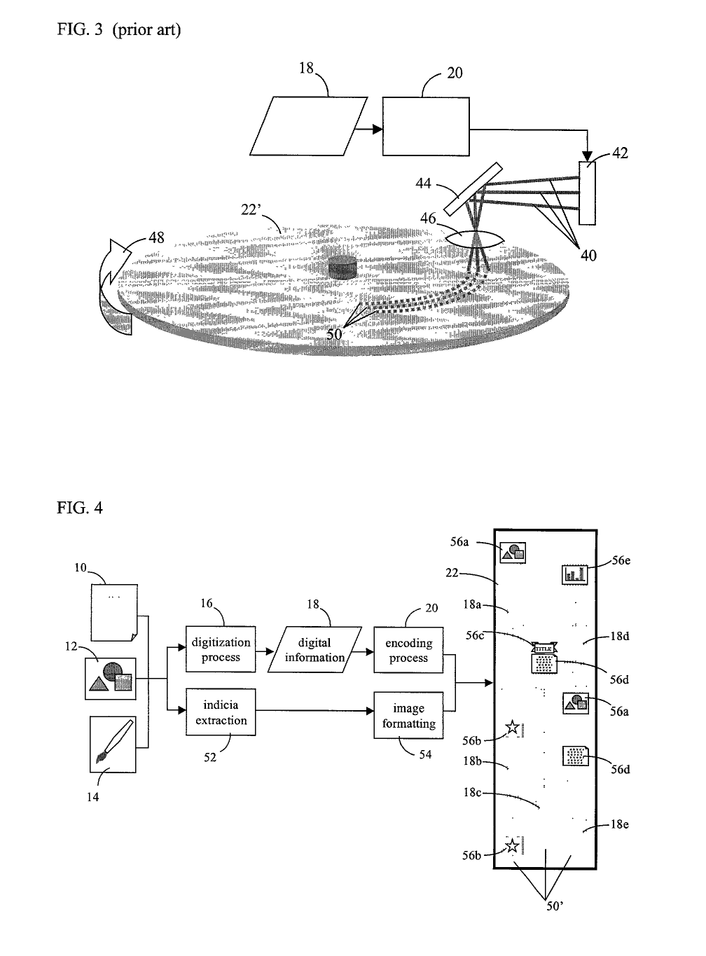

FIG. 3 illustrates a method for digital data recording on an optical recording medium according to the prior art. Digital data files 18 are processed by an encoder 20 creating a signal stream that modulates one or more laser beams 40 generated by a laser array 42. The laser beams are conditioned by optical elements such as a mirror 44 and directed through the aperture of an objective lens 46. The objective lens focuses the laser beams onto the recording surface of an optical recording medium 22′ that is moving with respect to the focused laser beams in a scanning direction 48. Marks are recorded where the focused laser beams interact with the recording layer. These marks form a band of data tracks 50 that extends in a longitudinal direction parallel to the media scanning direction. A data band in the context of this disclosure means one or more data tracks on a storage medium on which are recorded information from a data file.

In FIG. 3, the data tracks that comprise the data band are shown with a longitudinal orientation. The data tracks may alternatively be oriented perpendicular to the scanning direction; this can be accomplished by scanning the laser beam(s) in a direction that is not parallel to the media scanning direction. In either case, the data band is much wider than the focused spot 64 of a recording laser and adjacent data bands do not overlap. It will be appreciated that digital information may be formatted as data bands on recording media other than optical recording media.

According to the present invention, the archival performance of a digital data storage medium is enhanced by the inclusion of human-readable indicia with the digitally recorded data. Human-readable indicia are information elements derived, extracted, or summarized from information files, the images of which can be interpreted directly by a human viewer to aid in future identification or recovery of the information. Examples of human-readable indicia include thumbnail images, alphanumeric summary text, line drawings, decoding keys, and logos.

FIG. 4 illustrates a format for digital data recording with human-readable indicia. Information elements such as documents, drawings, or pictures (10, 12, and 14) are processed by a digitizer 16 to create digital data files 18. Digital encoding transformations are applied to the digital data files by an encoder 20.

The information elements are also processed by an indicia extraction system 52 that creates human-readable indicia that are indicative of the contents of the information element. The indicia are formatted by an image formatter 54 into a signal that is merged with the encoded digital data. The digital data is recorded on one or more data bands 50′ on the recording surface of a digital storage medium 22. Images of the formatted indicia 56a-e are also recorded on the storage medium. The index images are recorded on data bands adjacent to or embedded within the corresponding digital data files 18a-e. In the figure, an index drawing 56a is attached to digital data file 18a. Digital data file 18b is demarcated by logos 56b perhaps indicating the file type or the originating project. Digital data file 18c is preceded by text images of a title heading 56c and a document summary 56d. Images of a representative chart 56e and drawing or image 56a are embedded in data file 18d. Data file 18e is preceded by the text image of a document summary 56d.

The incorporation of human-readable indicia with digital data files is easily understood when the data is recorded on an optical recording medium. The concept is also applicable to recording on any type of digital storage system that creates data bands on a recording surface, whether or not the data band pattern is visible to the naked eye.

When viewed as images with an appropriate magnification, the patterns of human-readable indicia can be read and understood directly by a human being. They summarize the information of the source data file or information element, providing partial indication of the contents, format, data source, etc. But because the information content of the indicia is limited, the data cannot be recovered in its entirety from the indicia alone. Full recovery of the data requires readout of the digital data file.

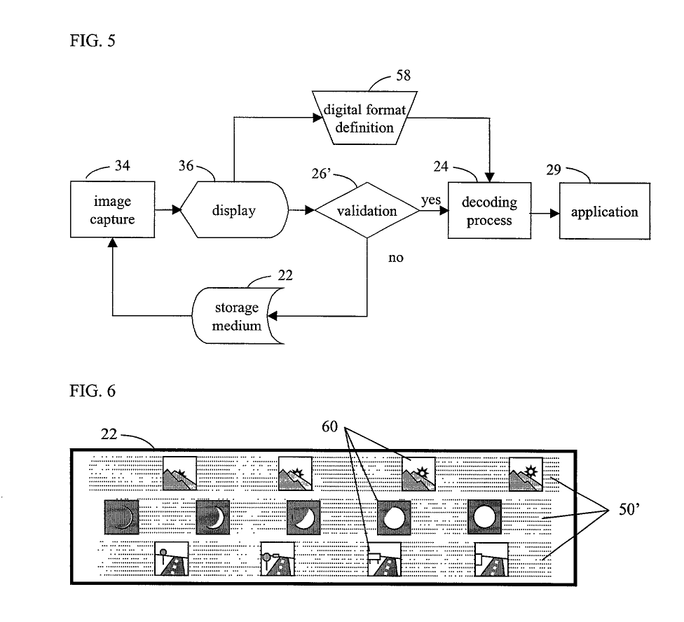

FIG. 5 describes a sequence for recovering archived digital data files with the aid of human-readable indicia including the steps of imaging the recording surface of the recording medium, examining the human-readable indicia to identify the location of a desired data file, and processing images of the data band to recover the digital data file. The recording surface of the digital storage medium 22 is imaged by an imaging system 34 and displayed to a user by an image display system 36. Evaluating the human-readable indicia imaged from the medium, the user performs a content validation check 26′ to determine whether the desired data file is present on the medium. If not, the user may reposition the medium to image a different section of the recording. When the user validates the presence of the desired data file, images of the recorded digital data pattern are captured and processed with reference to the definition 58 of the digital format by a decoder 24 to recreate the entire digital data file. The feasibility of successfully decoding the recorded data pattern is enhanced if the user can determine characteristics of the digital format and codes from the human-readable indicia.

Just as human-readable indicia recorded with individual data files can aid in the identification and recovery of the data file contents, so too human-readable indicia associated with a media unit can aid in high-level identification and readout of data contents. Such indicia may include alphanumeric text summarizing the media unit identification and directory contents. The media unit summary image(s) describe decoding protocols, readout equipment, or readout methods applicable to the media unit.

The high-level indicia images may be recorded on data bands in a leader or trailer portion of the medium where they are easily accessed by an imaging system.

The present invention is of particular value for archiving image-intensive data. FIG. 6 shows image files recorded with embedded human-readable indicia that includes thumbnail images. The storage medium 22 contains digitized image files recorded on data bands 50′. Thumbnail images 60 with lower resolution than the digitized images are embedded at intervals within the data bands. A thumbnail image may be inserted for each digitized image. For motion picture data files, it may be appropriate to provide one thumbnail image for a multiplicity of image frames. The recorded images cannot be extracted from the thumbnail images because of limitations in their image content and image characteristics. However, they do unambiguously identify the content of the associated digital image files. The generation of thumbnail images and their utility for indexing image data is described in commonly assigned U.S. Pat. No. 5,440,401, the disclosure of which is incorporated herein by reference.

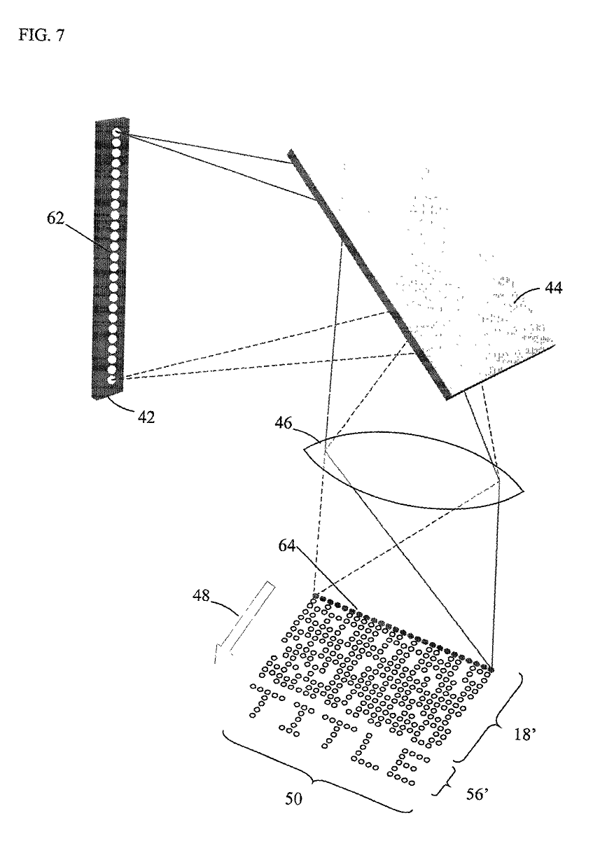

Human readable indicia can be recorded along with digital data files using known recording hardware. FIG. 7 shows the recording of such a format using a multi-channel optical recording head. A multi-channel recording signal drives a multiplicity of laser array elements 62 on a laser array 42. The laser beams are directed by optical elements such as mirror 44 to pass through an objective lens 46 that focuses them to a line of focused spots 64 on the recording surface of an optical recording medium. As the media surface scans past the objective lens, the focused spots 64 each form track of marks that is parallel to the scanning direction 48. The multiplicity of tracks formed by the array of focused spots 64 comprise a data band. By appropriate modulation of the laser elements, the pattern of marks on the data band may be organized to represent a human-readable indicium 56′ and then immediately switched to record a multitrack digital data file 18′. The resolution of human-readable indicia, which limits their image quality and flexibility, is limited by the number of tracks that comprise a data band. The recording method illustrated can be used to record a data band that is at least 100 tracks wide, which is suitable for recording all types of human-readable indicia including image thumbnails. Further details concerning optical data recording heads that record a wide data band are disclosed in commonly assigned U.S. Pat. No. 5,321,683, the disclosure of which is incorporated herein by reference.

The invention has been described in detail with particular reference to certain preferred embodiments thereof, but it will be understood that variations and modifications can be effected within the spirit and scope of the invention.

### Parts List

10 document
12 drawing
14 picture
16 digitizer
18 digital data files
18′ recorded digital data file
18a-e digital data files
20 encoder
22 digital storage medium
22′ optical recording medium
24 decoder
26 content validation check
26′ content validation check
28 display unit
29 data application
30 analog storage medium
32 recorded images
34 imaging system
36 image display system
38 displayed image
40 laser beams
42 laser array
44 mirror
46 objective lens
48 scanning direction
50 data band
50 ′ data bands
52 indicia extraction system

### Parts List (con't)

54 image formatter
56a-e formatted indicia
56′ human-readable indicium
58 digital format definition
60 thumbnail images
62 laser array elements
64 focused spots

1. A method for archival digital data storage, comprising the steps of:
a) processing a digital data file to generate one or more images that summarize the information content of the data file;
b) recording the data file in a digital format on a data band of a digital recording medium; and
c) recording the summary image(s) as human-readable indicia on a data band, such human-readable indicia being adjacent to or embedded within the digitally formatted data file.

2. The method of claim 1 wherein the digital recording medium is an optical recording medium.

3. The method of claim 2 wherein the data band includes a multiplicity of longitudinal data tracks, each recorded by an independently modulated laser beam.

4. The method of claim 1 wherein the digital data file includes images and the human-readable indicia include thumbnail images.

5. The method of claim 1 wherein the summary image(s) describe encoding methods used to format the digital data file or decoding methods that may be used to decode the data file.

6. The method of claim 1 further including:
d) generating one or more images that summarize the content of the media unit; and
e) recording the media unit summary images as human-readable indicia on the media unit.

7. The method of claim 6 wherein the media unit summary image(s) describe decoding protocols, readout equipment, or readout methods applicable to the media unit.

8. The method of claim 1 further comprising:
f) imaging the recording surface of the recording medium;
g) examining the human-readable indicia to identify the location of a desired data file; and
h) processing images of the data band to recover the digital data file.

9. An optical recording medium for archival digital data storage comprising:
a) the optical recording medium including one or more data bands with one or more data files recorded in a digital format on at least one data band; and
b) summary image(s) in the form of human-readable indicia recorded on a data band, such human-readable indicia being adjacent to or embedded within the digitally formatted data file(s).

10. The optical recording medium of claim 9 wherein such medium is an optical tape.

11. The optical recording medium of claim 10 wherein the data band includes a multiplicity of longitudinal data tracks, each recorded by an independently modulated laser beam.

12. The optical recording medium of claim 9 wherein the digital data file includes images and the human-readable indicia include thumbnail images.
